(19) United States
(12) Patent Application Publication
(10) Pub. No.: US 2023/0317749 A1
(43) Pub. Date: Oct. 5, 2023

(54) PHOTOELECTRIC CONVERSION DEVICE AND EQUIPMENT

(71) Applicant: CANON KABUSHIKI KAISHA, Tokyo (JP)

(72) Inventor: HIDEAKI ISHINO, Tokyo (JP)

(21) Appl. No.: 18/187,755

(22) Filed: Mar. 22, 2023

(30) Foreign Application Priority Data
Apr. 1, 2022 (JP) 2022-061961

(51) Int. Cl. H01L 27/146

(52) U.S. Cl. CPC H01L 27/14623; H01L 27/14612; H01L 27/14636

(57) ABSTRACT

A photoelectric conversion device having a first surface and a second surface is provided. A semiconductor layer including a pixel region and a shielded region light-shielded by a shielding layer is arranged between the first surface and the second surface, the shielding layer is arranged between the first surface and the semiconductor layer, and a structure including a pad electrode is arranged between the second surface and the semiconductor layer. The semiconductor layer includes a third surface in contact with the structure and a fourth surface, an opening extending from the first surface to the electrode and a trench extending from the third surface toward the fourth surface are arranged, the trench includes a portion arranged at least between the opening and the pixel region, and the portion is arranged so as to overlap the light shielding layer.

### BACKGROUND OF THE INVENTION

### Field of the Invention

The present invention relates to a photoelectric conversion device and equipment.

### Description of the Related Art

There is known a photoelectric conversion device including a pixel region in which a plurality of pixels including photoelectric conversion elements are arranged in an array and a light-shielding region. Japanese Patent Laid-Open No. 2015-162640 describes a semiconductor device including back-side illumination type photoelectric conversion elements including transistors light-shielded by a light-shielding film.

In the arrangement described in Japanese Patent Laid-Open No. 2015-162640, a groove portion is provided in a semiconductor substrate around an opening configured to expose a pad electrode provided in a pad region. Part of light having entered the opening is reflected by the groove portion, but light that entered a planarized film or an interlayer insulating film not provided with the groove portion around the opening may propagate in the semiconductor substrate and become stray light. If the stray light is photoelectrically converted by optical black pixels arranged in the light-shielded region or if the stray light intrudes into the pixel region and is photoelectrically converted by pixels arranged in the pixel region, the obtained image can deteriorate in quality.

Some embodiments of the present invention provide a technique advantageous in suppressing a deterioration in image quality.

### SUMMARY OF THE INVENTION

According to some embodiments, a photoelectric conversion device that comprises a first surface where light enters and a second surface on an opposite side of the first surface, wherein a semiconductor layer comprising a pixel region including a plurality of photoelectric conversion elements and a light-shielded region light-shielded by a light-shielding layer is arranged between the first surface and the second surface, the light-shielding layer is arranged between the first surface and the semiconductor layer, a wiring structure including a pad electrode is arranged between the second surface and the semiconductor layer, in an orthogonal projection with respect to the first surface, at least a part of the light-shielding layer is arranged between the pixel region and the pad electrode, the semiconductor layer comprises a third surface in contact with the wiring structure, and a fourth surface on an opposite side of the third surface, an opening extending from the first surface to the pad electrode and a trench structure extending from the third surface toward the fourth surface are further arranged, the trench structure includes a portion arranged at least between the opening and the pixel region, and in the orthogonal projection with respect to the first surface, the portion is arranged so as to overlap the light shielding layer, is provided.

Further features of the present invention will become apparent from the following description of exemplary embodiments (with reference to the attached drawings).

### BRIEF DESCRIPTION OF THE DRAWINGS

FIG. 1 is a plan view showing an arrangement example of a photoelectric conversion device according to an embodiment;

FIG. 2 is a sectional view showing an arrangement example of the photoelectric conversion device shown in FIG. 1;

FIG. 3 is a sectional view showing another arrangement example of the photoelectric conversion device shown in FIG. 1;

FIG. 4 is a sectional view showing still another arrangement example of the photoelectric conversion device shown in FIG. 1;

FIG. 5 is a sectional view showing still another arrangement example of the photoelectric conversion device shown in FIG. 1;

FIG. 6 is a sectional view showing still another arrangement example of the photoelectric conversion device shown in FIG. 1;

FIGS. 7A and 7B are views showing a method of manufacturing the photoelectric conversion device shown in FIG. 1;

FIGS. 8A and 8B are views showing the method of manufacturing the photoelectric conversion device shown in FIG. 1;

FIG. 9 is a view showing the method of manufacturing the photoelectric conversion device shown in FIG. 1; and

FIG. 10 is a view showing an arrangement example of equipment incorporating the photoelectric conversion device according to the embodiment.

### DESCRIPTION OF THE EMBODIMENTS

Hereinafter, embodiments will be described in detail with reference to the attached drawings. Note, the following embodiments are not intended to limit the scope of the claimed invention. Multiple features are described in the embodiments, but limitation is not made to an invention that requires all such features, and multiple such features may be combined as appropriate. Furthermore, in the attached drawings, the same reference numerals are given to the same or similar configurations, and redundant description thereof is omitted.

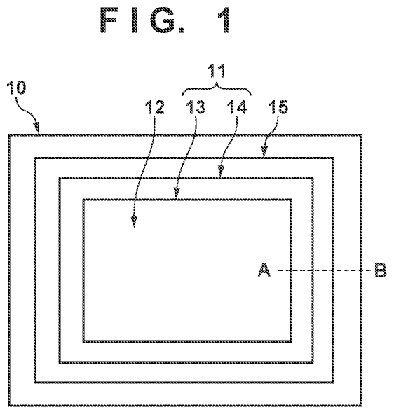

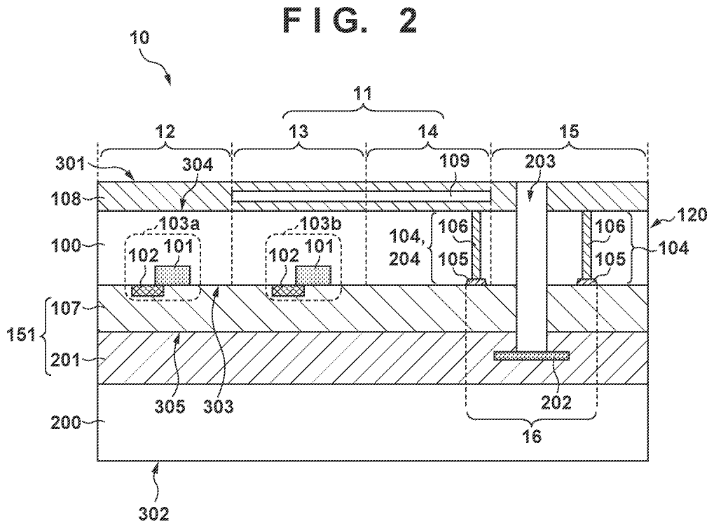

A photoelectric conversion device according to an embodiment of this disclosure will be described with reference to FIGS. 1 to 9. FIG. 1 is a plan view showing the schematic arrangement of a photoelectric conversion device 10 according to this embodiment. FIG. 1 shows the photoelectric conversion device 10 for one chip. FIG. 2 is a sectional view taken along a line A-B shown in FIG. 1.

The photoelectric conversion device 10 includes two principal surfaces, namely, a surface 301 where light enters and a surface 302 on the opposite side of the surface 301. A semiconductor layer 100 is arranged between the surface 301 and the surface 302 of the photoelectric conversion device. The semiconductor layer 100 includes a pixel region 12 including a plurality of photoelectric conversion elements 103a, and a light-shielded region 11 light-shielded by a light-shielding layer 109. In the semiconductor layer 100, a peripheral region 15 not covered with the light-shielding layer 109 may be further arranged between an end portion 120 of the semiconductor layer 100 and the light-shielded region 11. However, the semiconductor layer 100 is not limited to this, and may be covered with the light-shielding layer 109 up to the end portion 120 of the semiconductor layer 100.

The light-shielded region 11 includes a region 14 where a trench structure 104 (to be described later) is arranged, and a region 13 between the pixel region 12 and the region 14 arranged with the trench structure 104. A photoelectric conversion element 103b different from the plurality of photoelectric conversion elements 103a arranged in the pixel region 12 may be arranged in the region 13. The region 13 where the photoelectric conversion elements 103b are arranged can also be referred to as an optical black region. A drive circuit configured to drive the plurality of photoelectric conversion elements 103a arranged in the pixel region 12 may be arranged in the region 13 of the light-shielded region 11.

As shown in FIG. 2, the light-shielding layer 109 is arranged between the surface 301 of the photoelectric conversion device 10 and the semiconductor layer 100. In addition, a wiring structure 151 including a pad electrode 202 (to be described later) is arranged between the surface 302 of the photoelectric conversion device 10 and the semiconductor layer 100. The semiconductor layer 100 includes two principal surfaces, namely, a surface 303 in contact with the wiring structure 151 and a surface 304 on the opposite side of the surface 303. For example, a semiconductor material such as silicon is used for the semiconductor layer 100.

Diffusion layers 101, gate electrodes 102, and the like are arranged on the surface 303 side of the semiconductor layer 100, and they form photoelectric conversion elements 103a and 103b. The trench structure 104 extending from the surface 303 toward the surface 304 of the semiconductor layer 100 is arranged in the semiconductor layer 100. As shown in FIG. 2, the trench structure 104 may be formed by a shallow trench isolation 105 and a deep trench isolation 106. The deep trench isolation 106 extends from the bottom portion of the shallow trench isolation 105 toward the surface 304. As shown in FIG. 2, the trench structure 104 may extend through the semiconductor layer 100. However, the trench structure 104 is not limited to this, and the deep trench isolation 106 of the trench structure 104 need not reach the surface 304. Note that, even if the deep trench isolation 106 does not reach the surface 304, the trench structure 104 arranged as close to the surface 304 as possible can produce the stronger effect to be described later.

The wiring structure 151 is arranged on the surface 303 of the semiconductor layer 100. The wiring structure 151 includes a structure 107 formed on the surface 303 of the semiconductor layer 100 and a structure 201 formed on a support substrate 200, and both structures are formed in a manufacturing step to be described later. The wiring structure 151 includes a wiring pattern formed by conductors, and an interlayer insulating film. The structure 107 of the wiring structure 151 includes the gate electrode 102 of the transistor arranged in each of the plurality of photoelectric conversion elements 103a described above.

The support substrate 200 may be a simple substrate where various elements and the like have not been formed. Alternatively, the support substrate 200 may be a substrate equipped with functions such as an Application Specific Integrated Circuit (ASIC) and a memory. As has been described above, the structure 201 is formed on the semiconductor layer 100 side of the support substrate 200. If elements such as a transistor have not been formed in the support substrate 200, an insulating film alone may be arranged as the structure 201. Regardless of formation of the element such as the transistor, the structure 201 may include a wiring pattern formed by conductors and an interlayer insulating film. The semiconductor layer 100 and the support substrate 200 are joined via a joint face 305 where the surface of the structure 107 and the surface of the structure 201 are in contact with each other.

A structure 108 is arranged on the surface 304 of the semiconductor layer 100. The structure 108 can include an insulating film configured to inactivate the surface state of the surface 304 of the semiconductor layer 100, and optical structures such as an antireflection film, an in-layer lens, a color filter, and a microlens. Further, as has been described above, the light-shielding layer 109 configured to light-shield the light-shielded region 11 is arranged in the structure 108. The light-shielding layer 109 can be arranged close to the surface 304 of the semiconductor layer 100.

The pad electrode 202 configured to electrically connect the components such as the photoelectric conversion elements 103a and 103b arranged in the photoelectric conversion device 10 and a device outside the photoelectric conversion device 10 is arranged in the wiring structure 151. In the arrangement shown in FIG. 2, the pad electrode 202 is provided in the structure 201, but the arrangement of the pad electrode 202 is not limited to this. The pad electrode 202 may be provided in the structure 107. In addition, although one pad electrode 202 is shown in FIG. 2, a plurality of the pad electrodes 202 can be arranged in the photoelectric conversion device 10. Therefore, the pad electrodes 202 may be arranged in both the structure 107 and the structure 201. A part of the pad electrode 202 is exposed by an opening 203 extending from the surface 301 of the photoelectric conversion device 10 to the pad electrode 202.

In an orthogonal projection with respect to the surface 301 of the photoelectric conversion device 10, the trench structure 104 intermittently or continuously surrounds the opening 203. In the arrangement shown in FIG. 2, the opening 203 is continuously surrounded by the trench structure 104. Thus, the trench structure 104 functions as an insulating film that electrically separates the opening 203 from the semiconductor layer 100. The trench structure 104 may be filled with an insulator. Even in this case, the trench structure 104 need not be completely buried with the insulator and rather may have a space. Here, when the trench structure 104 continuously surrounds the opening 203, this means that, for example, the trench structure 104 circularly surrounds the opening 203 along the planar shape of the opening 203. When the trench structure 104 intermittently surrounds the opening 203, this means that the trench structure 104 is arranged along parts of the planar shape of the opening 203. This includes a case in which, for example, if the opening 203 has a rectangular planar shape, the trench structure 104 is arranged along sides of the rectangle but not arranged in portions along corners of the rectangle. This also includes a case in which the trench structure 104 is formed along, for example, three sides of the opening 203 having the rectangular planar shape but not formed along one remaining side.

The opening 203 and the trench structure 104 are arranged so as to be adjacent to each other. In other words, as shown in FIG. 2, elements other than the semiconductor layer 100, the elements forming the photoelectric conversion device 10, need not be arranged between the opening 203 and the trench structure 104 in the semiconductor layer 100. For example, the trench structure 104 can include a trench closest to the opening 203 among a plurality of trenches provided in the light-shielded region 11 of the semiconductor layer 100.

Next, the effect of this embodiment will be described. The trench structure 104 includes a portion 204 arranged at least between the opening 203 and the pixel region 12. If the trench structure 104 continuously surrounds the opening 203 as shown in FIG. 2, the portion 204 is a portion arranged closer to the pixel region than the opening 203. For example, the portion 204 refers to a region of the trench structure 104 where a virtual straight line connecting the opening 203 and the pixel region 12 without passing through the portion 204 does not exist in the orthogonal projection with respect to the surface 301 of the photoelectric conversion device 10. Further, in the orthogonal projection with respect to the surface 301 of the photoelectric conversion device 10, at least a part of the light-shielding layer 109 is arranged between the pixel region 12 and the pad electrode 202. At this time, in the orthogonal projection with respect to the surface 301 of the photoelectric conversion device 10, the portion 204 is arranged so as to overlap the light-shielding layer 109. Accordingly, as compared to a case in which the light-shielding layer 109 is not arranged above the portion 204, the light-shielding layer 109 can suppress light passing between the portion 204 and the surface 301 of the photoelectric conversion device 10 and entering the semiconductor layer 100 from the opening 203 or the structure 108. That is, it is possible to suppress that the light having entered from the opening 203 or the like becomes stray light and is photoelectrically converted by the photoelectric conversion element 103b arranged in the region 13 and further the photoelectric conversion element 103a arranged in the pixel region 12. As a result, a deterioration in image quality of an image obtained by the photoelectric conversion device 10 can be suppressed.

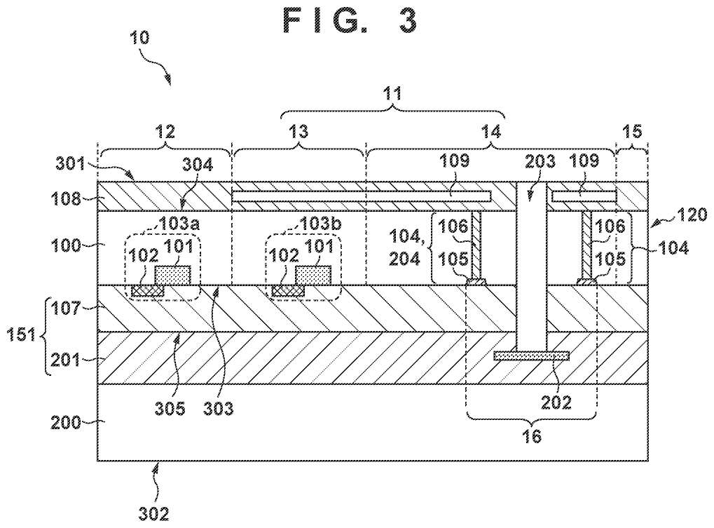

FIG. 3 is a view showing a modification of the sectional view of the photoelectric conversion device 10 shown in FIG. 2. In the sectional view shown in FIG. 3, the light-shielded region 11 covered with the light-shielding layer 109 extends to the end portion 120 of the semiconductor layer 100 beyond the pad electrode 202. As a result, in the orthogonal projection with respect to the surface 301 of the photoelectric conversion device 10, the pad electrode 202 is arranged in the region 14 of the light-shielded region 11. When the region where the pad electrode 202 and the trench structure 104 are arranged (in this embodiment, the region surrounded by the trench structure 104) is referred to as a pad region 16 as shown in FIG. 3, it can be said that the pad region 16 is arranged so as to overlap the region 14 of the light-shielded region 11 in the orthogonal projection with respect to the surface 301 of the photoelectric conversion device 10. To the contrary, in the arrangement shown in FIG. 2, it can be said that the pad region 16 is arranged so as to be across the region 14 of the light-shielded region 11 and the peripheral region 15. Further, as shown in FIGS. 2 and 3, the pad region 16 does not overlap the region 13 of the light-shielded region 11 where the photoelectric conversion element 103b is arranged.

Here, as shown in FIG. 3, the trench structure 104 may be arranged so as to entirely overlap the light-shielding layer 109 in the orthogonal projection with respect to the surface 301 of the photoelectric conversion device 10. With the arrangement shown in FIG. 3, the light-shielding layer 109 can suppress light passing between the trench structure 104 and the surface 301 of the photoelectric conversion device 10 and entering the semiconductor layer 100 from the opening 203 or the structure 108. As a result, as compared to the structure shown in FIG. 2, it is possible to further suppress that the light having entered from the opening 203 or the like becomes stray light, and a deterioration in image quality of an image obtained by the photoelectric conversion device 10 can be suppressed.

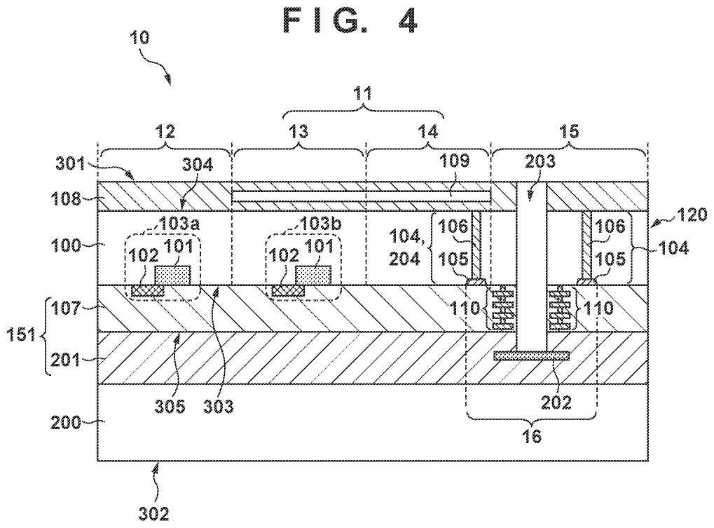

FIG. 4 is a view showing another modification of the sectional view of the photoelectric conversion device 10 shown in FIG. 2. In the arrangement shown in FIG. 4, a light-shielding pattern 110 configured to reflect light exiting from the opening 203 is arranged in the structure 107 of the wiring structure 151. This arrangement may be similar to that of the photoelectric conversion device 10 shown in FIG. 2 except for the light-shielding pattern 110, so that a description of the arrangement except for the light-shielding pattern 110 will be omitted.

The light-shielding pattern 110 can be formed by conductors arranged in the structure 107, for example, wiring patterns arranged in respective wiring layers, vias connecting the wiring layers, and the like. The opening 203 and the light-shielding pattern 110 are arranged so as to be adjacent to each other. In other words, as shown in FIG. 4, wiring patterns (conductors) other than the light-shielding pattern 110 need not be arranged between the opening 203 and the light-shielding pattern 110 in the structure 107. For example, the light-shielding pattern 110 can include the wiring pattern closest to the opening 203 among the wiring patterns arranged in the structure 107 of the wiring structure 151.

The light-shielding pattern 110 is arranged at least between the opening 203 and the pixel region 12. In the orthogonal projection with respect to the surface 301 of the photoelectric conversion device 10, the light-shielding pattern 110 may intermittently or continuously surround the opening 203. In the arrangement shown in FIG. 4, the opening 203 is continuously surrounded by the light-shielding pattern 110. For example, in the orthogonal projection with respect to the surface 301 of the photoelectric conversion device 10, a virtual straight line connecting the opening 203 and the pixel region 12 without passing through the light-shielding pattern 110 need not exist.

The light-shielding pattern 110 is provided in the structure 107 so as to be close to the opening 203. With this, it is also possible to suppress that the light having entered from the opening 203 enters the semiconductor layer 100 from the structure 107. As a result, as compared to the structure shown in FIG. 2, this structure can further suppress that the light entering having entered from the opening 203 or the like becomes stray light, and a deterioration in image quality of an image obtained by the photoelectric conversion device 10 is suppressed. In the arrangement shown in FIG. 4, the light-shielding pattern 110 is arranged in the structure 107 of the wiring structure 151, but the light-shielding pattern 110 may also be arranged in the structure 201.

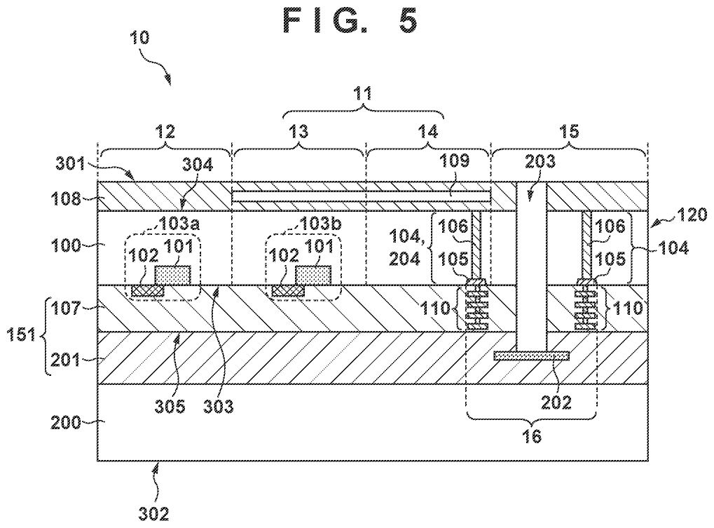

FIG. 5 is a view showing a modification of the sectional view of the photoelectric conversion device 10 shown in FIG. 4. As shown in FIG. 5, in the orthogonal projection with respect to the surface 301 of the photoelectric conversion device 10, a portion of the light-shielding pattern 110 arranged at least between the opening 203 and the pixel region 12 may include a portion overlapping the trench structure 104. In this case, in the orthogonal projection with respect to the surface 301 of the photoelectric conversion device 10, the portion of the light-shielding pattern 110 arranged at least between the opening 203 and the pixel region 12 can include a portion overlapping the light-shielding layer 109.

For example, in the orthogonal projection with respect to the surface 301 of the photoelectric conversion device 10, the portion of the light-shielding pattern 110 arranged between the opening 203 and the pixel region 12 may include a portion overlapping the portion 204 of the trench structure 104. Alternatively, for example, in a case in which the trench structure 104 and the light-shielding pattern 110 are arranged so as to surround the opening 203, in the orthogonal projection with respect to the surface 301 of the photoelectric conversion device 10, the light-shielding pattern 110 and the trench structure 104 may be arranged so as to overlap each other as shown in FIG. 3. The trench structure 104 and the light-shielding pattern 110 are arranged so as to overlap each other in the orthogonal projection with respect to the surface 301 of the photoelectric conversion device 10. With this, the effect of suppressing the stray light traveling from the opening 203 to the region 13 of the light-shielded region 11 and the pixel region 12 becomes higher than in the arrangement shown in FIG. 4. As a result, a deterioration in image quality of an image obtained by the photoelectric conversion device 10 is suppressed.

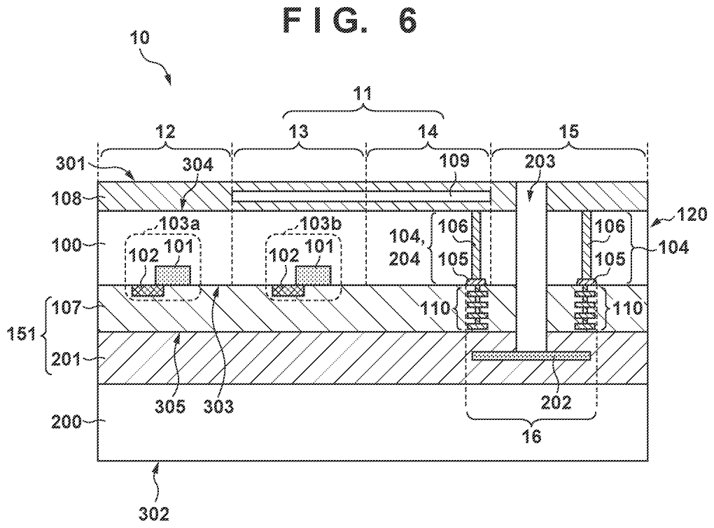

FIG. 6 is a view showing a modification of the sectional view of the photoelectric conversion device 10 shown in FIG. 5. As shown in FIG. 6, in the orthogonal projection with respect to the surface 301 of the photoelectric conversion device 10, the portion of the light-shielding pattern 110 arranged at least between the opening 203 and the pixel region 12 may include a portion overlapping the pad electrode 202. In this case, as shown in FIG. 6, in the orthogonal projection with respect to the surface 301 of the photoelectric conversion device 10, the pad electrode 202 may include a portion overlapping the light-shielding layer 109. In the orthogonal projection with respect to the surface 301 of the photoelectric conversion device 10, the portion 204 of the trench structure 104, the light-shielding pattern 110, and the pad electrode 202 are arranged so as to overlap each other. With this, the effect of suppressing the stray light traveling from the opening 203 to the region 13 of the light-shielded region 11 and the pixel region 12 becomes higher than in the arrangement shown in FIG. 5. As a result, a deterioration in image quality of an image obtained by the photoelectric conversion device 10 is suppressed.

Also in the arrangements shown in FIGS. 4 to 6, as in the arrangement shown in FIG. 3, the light-shielding layer 109 may be arranged close to the end portion 120 of the semiconductor layer 100. For example, also in the arrangements shown in FIGS. 4 to 6, as in the arrangement shown in FIG. 3, the pad region 16 may be arranged so as to overlap the region 14 of the light-shielded region 11 in the orthogonal projection with respect to the surface 301 of the photoelectric conversion device 10. With this, the effect of suppressing the stray light traveling from the opening 203 to the region 13 of the light-shielded region 11 and the pixel region 12 becomes higher, and a deterioration in image quality of an image obtained by the photoelectric conversion device 10 is suppressed. In this manner, the arrangements shown in FIGS. 2 to 6 may be used in combination with each other, as appropriate.

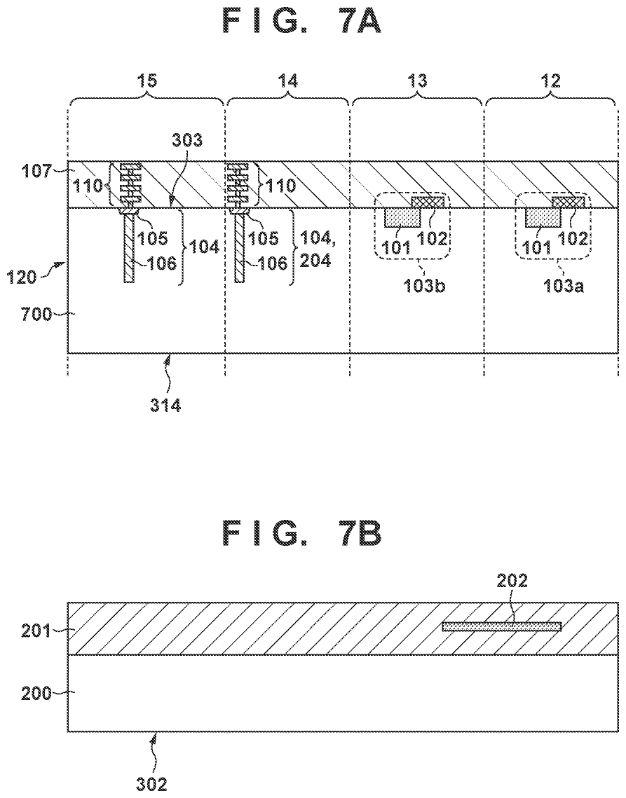

Next, with reference to FIGS. 7A to 9, a method of manufacturing the photoelectric conversion device 10 according to this embodiment will be described. Here, a description will be given using a method of manufacturing the arrangement shown in FIG. 6 described above, but the arrangement shown in FIGS. 2 to 5 can also be manufactured using a similar method.

First, as shown in FIG. 7A, a semiconductor substrate 700 for manufacturing the semiconductor layer 100 is prepared. The semiconductor substrate 700 includes the surface 303 and a surface 314 on the opposite side of the surface 303. For example, silicon or the like may be used for the semiconductor substrate 700. The trench structure 104 extending from the surface 303 toward the surface 314 is formed on the surface 303 of the semiconductor substrate 700. The trench structure 104 may include the deep trench isolation 106 and the shallow trench isolation 105. For example, the shallow trench isolation 105 may be formed on the surface 303 of the semiconductor substrate 700, and then the deep trench isolation 106 may be formed. The trench structure 104 is formed by arranging the deep trench isolation 106 and the shallow trench isolation 105 so as to overlap each other in an orthogonal projection with respect to the surface 303 of the semiconductor substrate 700. The trench structure 104 can be formed, for example, so as to surround a region where the opening 203 is to be formed later.

In the regions of the semiconductor substrate 700 to be the pixel region 12 and the region 13 of the light-shielded region 11, the diffusion layers 101 are formed by ion implantation. Further, the gate electrodes 102 are formed in the regions to be the pixel region 12 and the region 13 of the light-shielded region 11. For example, the gate electrodes 102 are formed by depositing polysilicon on the surface 303 of the semiconductor substrate 700 and patterning the deposited polysilicon. In FIG. 7A and FIGS. 2 to 6 described above, the photoelectric conversion elements 103a and 103b each including one diffusion layer 101 and one gate electrode 102 are shown in the pixel region 12 and the region 13 of the light-shielded region 11, respectively, but in practice, more elements and components of the respective elements are arranged.

After the trench structure 104 and the photoelectric conversion elements 103a and 103b are formed in the semiconductor substrate 700, the structure 107 as a part of the wiring structure 151 is formed on the surface 303 of the semiconductor substrate 700. The structure 107 can include an interlayer insulating film, wiring patterns each containing copper or aluminum as a main component, a contact plug connecting the semiconductor substrate 700 and the wiring pattern, a via plug connecting the wiring patterns, and the like, but details thereof will be omitted. When forming the structure 107, the light-shielding pattern 110 may be provided so as to surround a region where the opening 203 is to be formed later. In addition, the trench structure 104 (portion 204) and the light-shielding pattern 110 may be arranged so as to overlap each other in the orthogonal projection with respect to the surface 303 of the semiconductor substrate 700.

Further, the support substrate 200 is prepared as shown in FIG. 7B. The support substrate 200 may be a substrate where various elements and the like have not been formed. Alternatively, the support substrate 200 may be a substrate equipped with functions such as an ASIC and a memory. For example, a semiconductor substrate made of silicon or the like may be used as the support substrate 200.

The structure 201 of the wiring structure 151 is formed on the surface (the surface on the opposite side of the surface to be the surface 302 of the photoelectric conversion device 10) of the support substrate 200. If elements such as a transistor have not been formed in the support substrate 200, an insulating film alone may be arranged as the structure 201.

Alternatively, elements such as a transistor may be formed as the structure 201. Even if the elements such as a transistor have been formed, a wiring pattern and an interlayer insulating film may be further arranged. In this case, the pad electrode 202 may be formed upon forming the structure 201. In this embodiment, a case in which the pad electrode 202 is arranged in the structure 201 is shown, but the pad electrode 202 may be arranged in the structure 107.

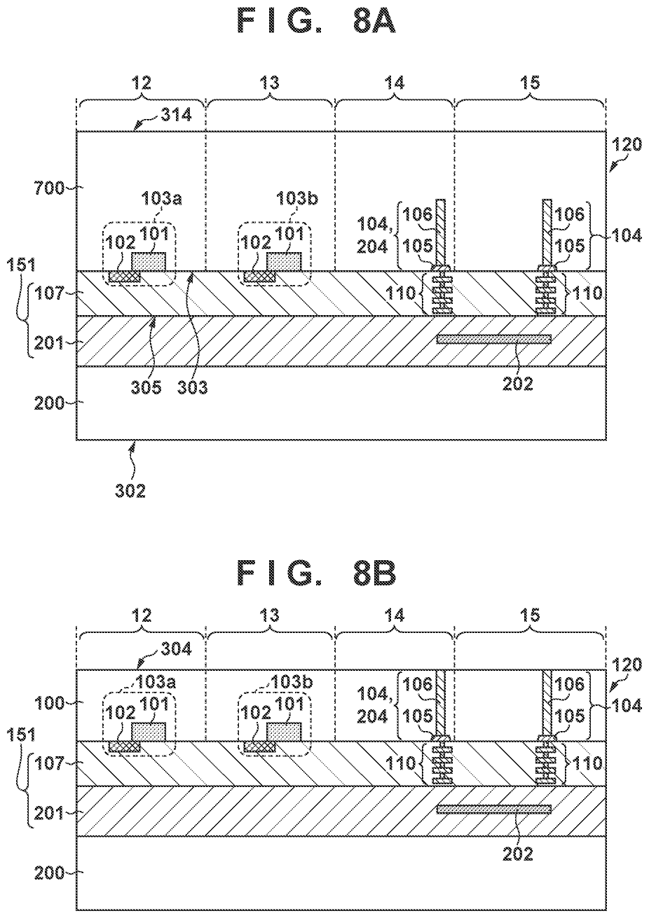

After forming the structure 107 on the semiconductor substrate 700 and the structure 201 on the support substrate 200, as shown in FIG. 8A, the semiconductor substrate 700 and the support substrate 200 are joined such that the surface of the structure 107 on the semiconductor substrate 700 and the surface of the structure 201 on the support substrate 200 form the joint face 305. The semiconductor substrate 700 may be joined to the support substrate 200 by activating the surface of the structure 107 and the surface of the structure 201 by plasma irradiation, that is, a so-called cold joining method. However, the present invention is not limited to this and, for example, the semiconductor substrate 700 may be joined to the support substrate 200 by adhering the structure 107 to the structure 201 via a joining member having adhesiveness.

Then, as shown in FIG. 8B, the semiconductor substrate 700 is thinned from the surface 314 side. Thus, the surface 304 of the semiconductor layer 100 is formed from the semiconductor substrate 700. The thickness of the semiconductor layer 100 after thinning can be set to a thickness with which the trench structure 104 is exposed from the surface 304 of the semiconductor layer 100. In this case, the insulator filling the trench structure 104 may be used as an etching stop material during thinning the semiconductor substrate 700 to form the semiconductor layer 100.

However, the thickness of the semiconductor layer 100 is not limited to this. For example, thinning may be stopped before the trench structure 104 is exposed from the surface 304 of the semiconductor layer 100. In order to form the semiconductor layer 100 by thinning the semiconductor substrate 700, a grinder device, a wet etching device, a CMP device, or the like can be used.

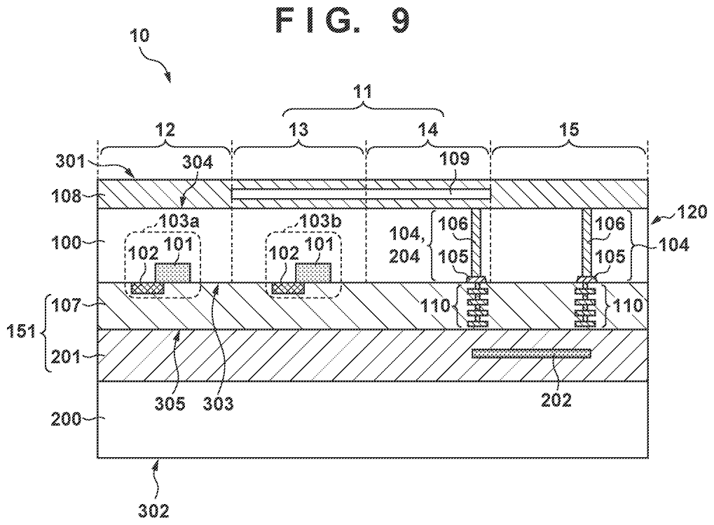

After the semiconductor layer 100 is formed by thinning the semiconductor substrate 700, the structure 108 is formed on the surface 304 of the semiconductor layer 100 as shown in FIG. 9. The structure 108 includes an insulating film configured to inactivate the surface state of the surface 304 of the semiconductor layer 100. The structure 108 also includes optical structures for guiding light having entered the structure 108 (the surface 301 of the photoelectric conversion device 10) to the photoelectric conversion element 103a, for example, an antireflection film, an in-layer lens, a color filter, a microlens, and the like. Further, the light-shielding layer 109 is formed in the structure 108 near the surface 304 of the semiconductor layer 100. The light-shielding layer 109 is arranged so as to cover the entire light-shielded region 11. Tungsten, aluminum, or titanium nitride can be used for the light-shielding layer 109.

Then, the opening 203 is formed from the structure 108 toward the pad electrode 202, thereby exposing the pad electrode 202. With this, the photoelectric conversion device 10 shown in FIG. 6 can be manufactured. In the above-described steps, by changing the region where the light-shielding layer 109 is arranged and the location where the light-shielding pattern 110 is arranged, the arrangements shown in FIGS. 2 and 5 can also be manufactured.

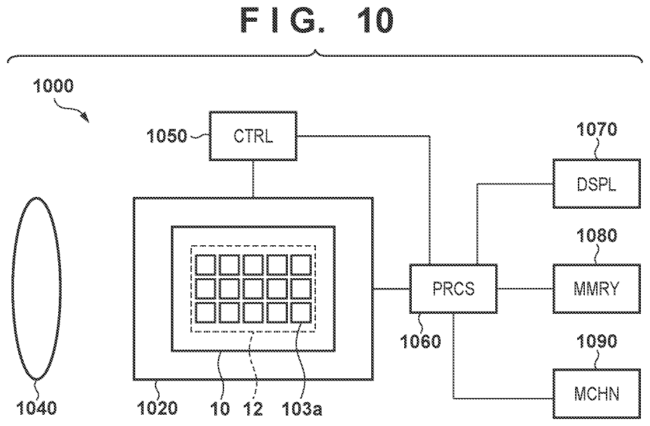

Equipment 1000 including the photoelectric conversion device 10 shown in FIG. 10 will be described below in detail. The photoelectric conversion device 10 can be accommodated in a package 1020 and mounted in the equipment 1000. The package 1020 can include a base on which the photoelectric conversion device 10 is fixed and a cover made of glass or the like facing the pixel region 12 of the photoelectric conversion device 10. The package 1020 can further include a joining member such as a bonding wire and bump for connecting a terminal of the base and an output terminal such as the pad electrode 202 of the photoelectric conversion device 10.

The equipment 1000 can include at least one of an optical device 1040, a control device 1050, a processing device 1060, a display device 1070, a storage device 1080, and a mechanical device 1090. The optical device 1040 is implemented by, for example, a lens, a shutter, and a mirror. The control device 1050 controls the photoelectric conversion device 10. The control device 1050 is, for example, a semiconductor device such as an ASIC.

The processing device 1060 processes a signal output from the photoelectric conversion device 10. The processing device 1060 is a semiconductor device such as a CPU or an ASIC for forming an Analog Front End (AFE) or a Digital Front End (DFE). The display device 1070 is an EL display device or a liquid crystal display device that displays information (image) obtained by the photoelectric conversion device 10. The storage device 1080 is a magnetic device or a semiconductor device that stores the information (image) obtained by the photoelectric conversion device 10. The storage device 1080 is a volatile memory such as an SRAM or a DRAM, or a nonvolatile memory such as a flash memory or a hard disk drive.

The mechanical device 1090 includes a moving or propulsion unit such as a motor or an engine. In the equipment 1000, the signal output from the photoelectric conversion device 10 is displayed on the display device 1070 or transmitted to an external device by a communication device (not shown) included in the equipment 1000. Hence, the equipment 1000 may further include the storage device 1080 and the processing device 1060 in addition to the memory circuits and arithmetic circuits included in the photoelectric conversion device 10. The mechanical device 1090 may be controlled based on the signal output from the photoelectric conversion device 10.

In addition, the equipment 1000 is suitable for electronic equipment such as an information terminal (for example, a smartphone or a wearable terminal) which has a shooting function or a camera (for example, an interchangeable lens camera, a compact camera, a video camera, or a monitoring camera). The mechanical device 1090 in the camera can drive the components of the optical device 1040 in order to perform zooming, an in-focus operation, and a shutter operation. Alternatively, the mechanical device 1090 in the camera can move the photoelectric conversion device 10 in order to perform an anti-vibration operation.

Furthermore, the equipment 1000 can be a transportation equipment such as a vehicle, a ship, or an airplane. The mechanical device 1090 in the transportation equipment can be used as a moving device. The equipment 1000 as the transportation equipment may be applied to a device that transports the photoelectric conversion device 10 or a device that uses an image capturing function to assist and/or automate driving (steering). The processing device 1060 for assisting and/or automating driving (steering) can perform, based on the information obtained by the photoelectric conversion device 10, processing for operating the mechanical device 1090 as a moving device. Alternatively, the equipment 1000 may be medical equipment such as an endoscope, measurement equipment such as a distance measurement sensor, analysis equipment such as an electron microscope, or office equipment such as a copy machine, or industrial equipment such as a robot.

According to the present invention, it is possible to provide a technique advantageous in suppressing a deterioration in image quality.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2022-061961, filed Apr. 1, 2022, which is hereby incorporated by reference herein in its entirety.

What is claimed is:

1. A photoelectric conversion device that comprises a first surface where light enters and a second surface on an opposite side of the first surface, wherein
a semiconductor layer comprising a pixel region including a plurality of photoelectric conversion elements and a light-shielded region light-shielded by a light-shielding layer is arranged between the first surface and the second surface,
the light-shielding layer is arranged between the first surface and the semiconductor layer,
a wiring structure including a pad electrode is arranged between the second surface and the semiconductor layer,
in an orthogonal projection with respect to the first surface, at least a part of the light-shielding layer is arranged between the pixel region and the pad electrode,
the semiconductor layer comprises a third surface in contact with the wiring structure, and a fourth surface on an opposite side of the third surface,
an opening extending from the first surface to the pad electrode and a trench structure extending from the third surface toward the fourth surface are further arranged,
the trench structure includes a portion arranged at least between the opening and the pixel region, and
in the orthogonal projection with respect to the first surface, the portion is arranged so as to overlap the light shielding layer.

2. The device according to claim 1, wherein
in the orthogonal projection with respect to the first surface, the trench structure intermittently or continuously surrounds the opening.

3. The device according to claim 1, wherein
in the orthogonal projection with respect to the first surface, a virtual straight line connecting the opening and the pixel region without passing through the portion does not exist.

4. The device according to claim 1, wherein
the trench structure includes a trench closest to the opening among a plurality of trenches provided in the light-shielded region of the semiconductor layer.

5. The device according to claim 1, wherein
in the semiconductor layer, a peripheral region not covered with the light-shielding layer is further arranged between an end portion of the semiconductor layer and the light-shielded region, and
in the orthogonal projection with respect to the first surface, the pad electrode is arranged in the light-shielded region.

6. The device according to claim 1, wherein
in the orthogonal projection with respect to the first surface, the trench structure is arranged so as to entirely overlap the light-shielding layer.

7. The device according to claim 1, wherein
a light-shielding pattern configured to reflect light exiting from the opening is arranged in the wiring structure, and
the light-shielding pattern is arranged at least between the opening and the pixel region.

8. The device according to claim 7, wherein
in the orthogonal projection with respect to the first surface, the light- shielding pattern surrounds the opening.

9. The device according to claim 7, wherein
in the orthogonal projection with respect to the first surface, a portion of the light-shielding pattern arranged at least between the opening and the pixel region includes a portion overlapping the pad electrode.

10. The device according to claim 7, wherein
in the orthogonal projection with respect to the first surface, a portion of the light-shielding pattern arranged at least between the opening and the pixel region includes a portion overlapping the trench structure.

11. The device according to claim 7, wherein
in the orthogonal projection with respect to the first surface, a portion of the light-shielding pattern arranged at least between the opening and the pixel region includes a portion overlapping the light-shielding layer.

12. The device according to claim 7, wherein
in the orthogonal projection with respect to the first surface, the light- shielding pattern includes a wiring pattern closest to the opening among wiring patterns arranged in the wiring structure.

13. The device according to claim 1, wherein
a photoelectric conversion element different from the plurality of photoelectric conversion elements is arranged in a region of the light-shielded region between the trench structure and the pixel region.

14. The device according to claim 1, wherein
a drive circuit configured to drive the plurality of photoelectric conversion elements is arranged in a region of the light-shielded region between the trench structure and the pixel region.

15. The device according to claim 1, wherein
the trench structure extends through the semiconductor layer.

16. The device according to claim 1, wherein
the wiring structure includes a gate electrode of a transistor arranged in each of the plurality of photoelectric conversion elements.

17. The device according to claim 1, wherein
the trench structure is filled with an insulator.

18. Equipment comprising:
the photoelectric conversion device according to claim 1; and
a processing device configured to process a signal output from the photoelectric conversion device.
